(19) United States
(12) Patent Application Publication
(10) Pub. No.: US 2024/0304667 A1
(43) Pub. Date: Sep. 12, 2024

(54) SEMICONDUCTOR DEVICES AND METHODS OF MANUFACTURING THEREOF

(71) Applicant: Taiwan Semiconductor Manufacturing Company, Ltd., Hsinchu (TW)

(72) Inventors: Huang-Lin Chao, Hillsboro, OR (US); Shen-Yang Lee, Miaoli County (TW); Hsiang-Pi Chang, New Taipei City (TW)

(73) Assignee: Taiwan Semiconductor Manufacturing Company, Ltd., Hsinchu (TW)

(21) Appl. No.: 18/179,519

(22) Filed: Mar. 7, 2023

(51) Int. Cl. H01L 29/06; H01L 29/423; H01L 29/51; H01L 29/66; H01L 29/775; H01L 29/786

(52) U.S. Cl. CPC H01L 29/0673; H01L 29/42392; H01L 29/517; H01L 29/66439; H01L 29/66545; H01L 29/775; H01L 29/78696

(57) ABSTRACT

A method for fabricating a semiconductor device is disclosed. The method includes exposing one or more surfaces of a conduction channel of a transistor, overlaying the one or more surfaces with a first high-k dielectric layer; overlaying the first high-k dielectric layer with a second high-k dielectric layer; depositing a ruthenium-containing layer over the second high-k dielectric layer; and performing a first annealing process with a temperature not greater than a threshold so as to remove oxygen vacancies from at least the first high-k dielectric layer.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of a gate-all-around (GAA) field-effect-transistor (FET) device, in accordance with some embodiments.

FIG. 2 illustrates a flow chart of an example method for making a non-planar transistor device, in accordance with some embodiments.

FIGS. 3, 4, 5, 6, 7, 8, 9, 10, 11, 12, 13, 14, 15, 16, and 17 illustrate cross-sectional views of an example GAA FET device (or a portion of the example GAA FET device) during various fabrication stages, made by the method of FIG. 2, in accordance with some embodiments.

FIGS. 18, 19, 20, 21, 22, 23, 24, 25, 26, 27, 28, 29, 30, 31, and 32 illustrate cross-sectional views of a number of example GAA FET devices during various fabrication stages, made based on the method of FIG. 2, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with continuing advance to the next generation of transistor architectures, the dimensions of a single transistor have become increasingly smaller. The dimensions of various features and/or spacing between adjacent features of a transistor have become smaller, which can significantly make processes of the transistor challenging. For example, a transistor using multiple nanostructures (e.g., nanosheets) as its conduction channel has been proposed as the next generation transistor architecture. In such an architecture, the spacing between adjacent nanostructures is typically smaller, which makes forming a gate structure with decent quality to wrap around each of the nanostructures significantly difficult. When forming the gate structure, which typically includes at least one high-k dielectric layer and at least one metal layer, a certain amount of oxygen vacancies. In general, these vacancies adversely impact performance of the transistor such as, for example, undesirable shift of the threshold voltage. In this regard, existing technologies has proposed to use high-temperature annealing (e.g., higher than about 750° C.) and/or deposit one or more additional capping layers to cure (e.g., fill) the vacancies. However, any of such existing approaches can significantly complicate the process of forming a transistor. Thus, the existing technologies for forming transistors have not been entirely satisfactory in some aspects.

Embodiments of the present disclosure are discussed in the context of forming a nanostructure field-effect-transistor (FET) device (sometimes referred to as a gate-all-around (GAA) FET device), and in particular, in the context of forming a replacement gate of a GAA FET device. For example, in some aspects of the present disclosure, a ruthenium-containing layer is formed over one or more high-k dielectric layers wrapping each of nanostructures (e.g., nanosheets) of the GAA FET device. In some embodiments, such a ruthenium-containing layer may consist of ruthenium or ruthenium oxide, which can be later utilized to cure (e.g., fill) any oxygen vacancies present in the one or more high-k dielectric layers through a low-temperature annealing process (e.g., with a temperature not greater than 550° C.). Further, in some aspects of the present disclosure, the ruthenium-containing layer that has cured the oxygen vacancies may be removed, followed by deposition of one or more work function metal layers to form a metal gate of the GAA FET device. In some other aspects of the present disclosure, the ruthenium-containing layer may remain after curing the oxygen vacancies. As such, the ruthenium-containing layer may function as a part or a whole of the metal gate of the GAA FET device. By forming the ruthenium-containing layer, a less number of layers are required to cure the oxygen vacancies, which can significantly ease the process of forming a GAA FET device. Moreover, using such a single layer to cure the vacancies can allow the disclosed method to be more easily adopted by the future technologies.

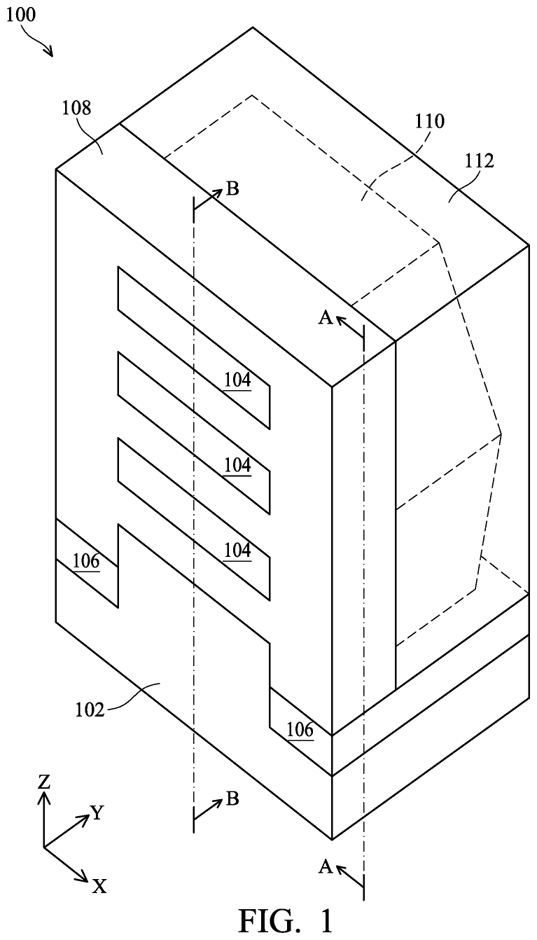

FIG. 1 illustrates a perspective view of an example nanostructure transistor device (e.g., a GAA FET device) 100, in accordance with various embodiments. The GAA FET device 100 includes a substrate 102 and a number of nanostructures (e.g., nanosheets, nanowires, etc.) 104 above the substrate 102. The semiconductor layers 104 are vertically separated from one another. Isolation regions 106 are formed on opposing sides of a protruded portion of the substrate 102, with the nanostructures 104 disposed above the protruded portion. A gate structure 108 wraps around each of the nanostructures 104 (e.g., a full perimeter of each of the nanostructures 104). Source/drain structures are disposed on opposing sides of the gate structure 108, e.g., source/drain structure 110 shown in FIG. 1. An interlayer dielectric (ILD) 112 is disposed over the source/drain structure 110.

It should be appreciated that FIG. 1 depicts a simplified GAA FET device, and thus, one or more features of a completed GAA FET device may not be shown in FIG. 1. For example, the other source/drain structure opposite the gate structure 108 from the source/drain structure 110 and the ILD disposed over such a source/drain structure are not shown in FIG. 1. Further, FIG. 1 is provided as a reference to illustrate a number of cross-sections in subsequent figures. As indicated, cross-section A-A is cut along a longitudinal axis of the gate structure 108 (e.g., in the X direction); and cross-section B-B is cut along a longitudinal axis of one of the semiconductor layers 104 and in a direction of a current flow between the source/drain structures (e.g., in the Y direction). Subsequent figures may refer to these reference cross-sections for clarity.

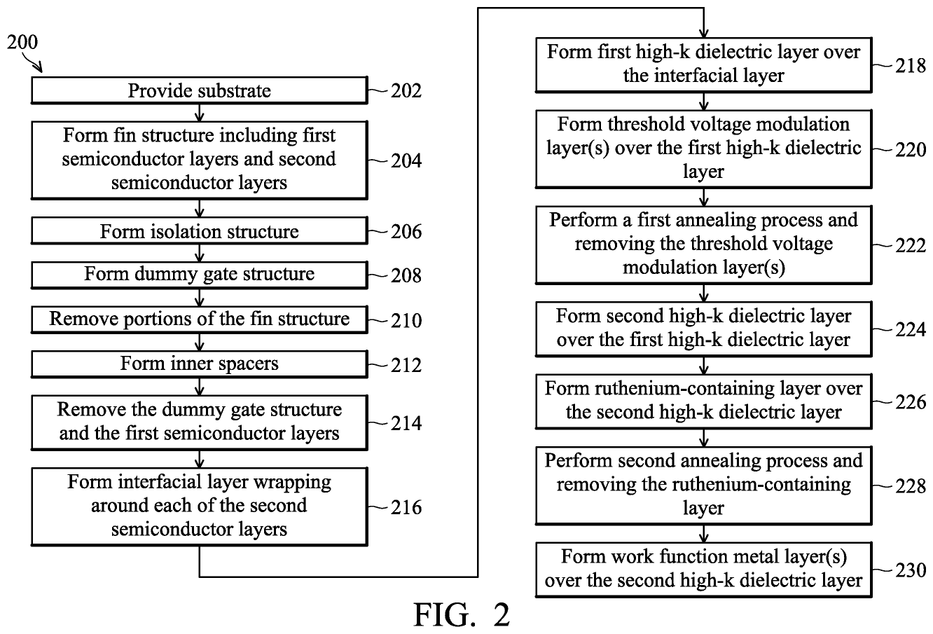

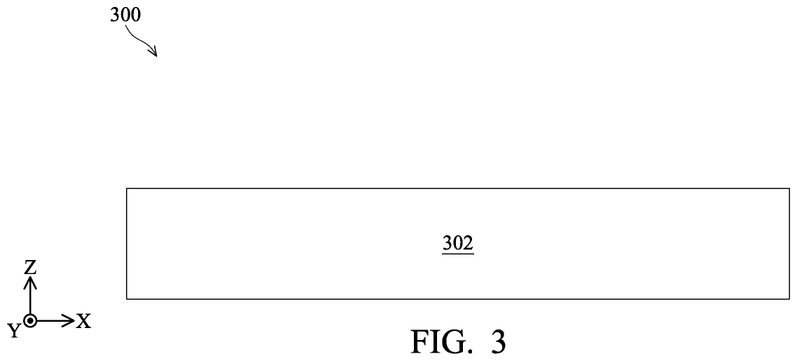

FIG. 2 illustrates a flowchart of a method 200 to form a nanostructure transistor device, according to one or more embodiments of the present disclosure. For example, at least some of the operations (or steps) of the method 200 can be used to form a FinFET device, a GAA FET device (e.g., GAA FET device 100), a nanosheet transistor device, a nanowire transistor device, a vertical transistor device, at least a portion of a complementary field-effect-transistor device, or the like. It is noted that the method 200 is merely an example, and is not intended to limit the present disclosure. Accordingly, it is understood that additional operations may be provided before, during, and after the method 200 of FIG. 2, and that some other operations may only be briefly described herein. In some embodiments, operations of the method 200 may be associated with cross-sectional views of an example GAA FET device at various fabrication stages as shown in FIGS. 3, 4A, 4B, 5A, 5B, 5C, 6A, 6B, 6C, 7A, 7B, 7C, 8, 9A, 9B, 9C, 9D, 9E, 10A, 10B, 10C, 10D, 10E, 11A, 11B, 11C, 11D, 11E, 11F, 11G, 11H, 11I, 11J, and 11K, respectively, which will be discussed in further detail below.

In brief overview, the method 200 starts with operation 202 of providing a substrate. The method 200 continues to operation 204 of forming a fin structure including a number of first semiconductor layers and a number of second semiconductor layers. The method 200 continues to operation 206 of forming an isolation structure. The method 200 continues to operation 208 of forming a dummy gate structure. The method 200 continues to operation 210 of removing portions of the fin structure. The method 200 continues to operation 212 of forming inner spacers. The method 200 continues to operation 214 of removing the dummy gate structure and the first semiconductor layers. The method 200 continues to operation 216 of forming an interfacial layer wrapping around each of the second semiconductor layers. The method 200 continues to operation 218 of forming a first high-k dielectric layer over the interfacial layer. The method 200 continues to operation 220 of forming one or more threshold voltage modulation layers over the first high-k dielectric layer. The method 200 continues to operation 222 of performing a first annealing process and removing the one or more threshold voltage modulation layers. The method 200 continues to operation 224 of forming a second high-k dielectric layer over the first high-k dielectric layer. The method 200 continues to operation 226 of forming a ruthenium-containing layer over the second high-k dielectric layer. The method 200 continues to operation 228 of performing a second annealing process and removing the ruthenium-containing layer. The method 200 continues to operation 230 of forming one or more work function metal layers over the second high-k dielectric layer to form an active gate structure.

As mentioned above, FIGS. 3-11K each illustrate, in a cross-sectional view, a portion of a GAA FET device 300 at various fabrication stages of the method 200 of FIG. 2. The GAA FET device 300 is similar to the GAA FET device 100 shown in FIG. 1, but with certain features/structures/regions not shown, for the purposes of brevity. For example, the following figures of the GAA FET device 300 do not include source/drain structures (e.g., 110 of FIG. 1). It should be understood the GAA FET device 300 may further include a number of other devices (not shown in the following figures) such as inductors, fuses, capacitors, coils, etc., while remaining within the scope of the present disclosure.

Corresponding to operation 202 of FIG. 2, FIG. 3 is a cross-sectional view of the GAA FET device 300 including a semiconductor substrate 302 at one of the various stages of fabrication. The cross-sectional view of FIG. 3 is cut in a direction perpendicular to the lengthwise direction of an active/dummy gate structure of the GAA FET device 300 (e.g., cross-section A-A indicated in FIG. 1).

The substrate 302 may be a semiconductor substrate, such as a bulk semiconductor, a semiconductor-on-insulator (SOI) substrate, or the like, which may be doped (e.g., with a p-type or an n-type dopant) or undoped. The substrate 302 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 302 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

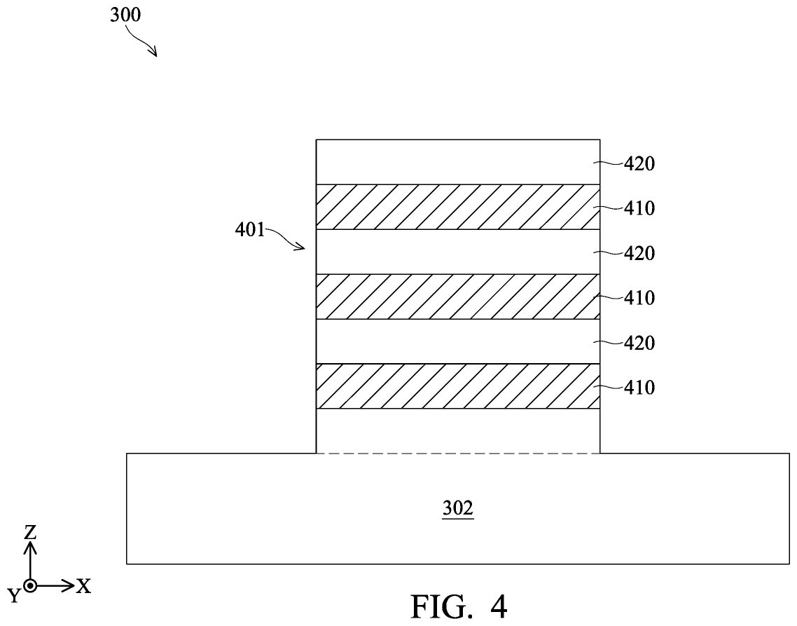

Corresponding to operation 204 of FIG. 2, FIG. 4 is a cross-sectional view of the GAA FET device 300 including a number of first semiconductor layers 410 and a number of second semiconductor layers 420 formed on the substrate 302 at one of the various stages of fabrication. The cross-sectional view of FIG. 4 is cut in a direction perpendicular to the lengthwise direction of an active/dummy gate structure of the GAA FET device 300 (e.g., cross-section A-A indicated in FIG. 1).

As shown, the first semiconductor layers 410 and the second semiconductor layers 420 are alternatingly disposed on top of one another (e.g., along the Z direction) to form a stack. For example, one of the second semiconductor layers 420 is disposed over one of the first semiconductor layers 410 then another one of the first semiconductor layers 420 is disposed over the second semiconductor layer 410, so on and so forth. The stack may include any number of alternately disposed first and second semiconductor layers 410 and 420, respectively. For example in FIG. 4, the first stack includes 3 first semiconductor layers 410, with 3 second semiconductor layers 420 alternatingly disposed therebetween and with one of the second semiconductor layers 420 being the topmost semiconductor layer. It should be understood that the GAA FET device 300 can include any number of first semiconductor layers and any number of second semiconductor layers, with either one of the first or second semiconductor layers being the topmost semiconductor layer, while remaining within the scope of the present disclosure.

The semiconductor layers 410 and 420 may have respective different thicknesses. Further, the first semiconductor layers 410 may have different thicknesses from one layer to another layer. The second semiconductor layers 420 may have different thicknesses from one layer to another layer. The thickness of each of the semiconductor layers 410 and 420 may range from few nanometers to few tens of nanometers. The first layer of the stack may be thicker than other semiconductor layers 410 and 420. In an embodiment, each of the first semiconductor layers 410 has a thickness ranging from about 5 nanometers (nm) to about 20 nm, and each of the second semiconductor layers 420 has a thickness ranging from about 5 nm to about 20 nm.

The two semiconductor layers 410 and 420 have different compositions. In various embodiments, the two semiconductor layers 410 and 420 have compositions that provide for different oxidation rates and/or different etch selectivity between the layers. In an embodiment, the first semiconductor layers 410 include silicon germanium (Si₁₋ₓGeₓ), and the second semiconductor layers include silicon (Si). In an embodiment, each of the semiconductor layers 420 is silicon that may be undoped or substantially dopant-free (i.e., having an extrinsic dopant concentration from about 0 cm⁻³ to about 1×10¹⁷ cm₋₃), where for example, no intentional doping is performed when forming the layers 420 (e.g., of silicon). In some embodiments, each of the semiconductor layers 410 is Si₁₋ₓGeₓ that includes less than 50% (x<0.5) Ge in molar ratio. For example, Ge may comprise about 15% to 35% of the semiconductor layers 410 of Si₁₋ₓGeₓ in molar ratio. Furthermore, the first semiconductor layers 410 may include different compositions among them, and the second semiconductor layers 420 may include different compositions among them.

Either of the semiconductor layers 410 and 420 may include other materials, for example, a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, or combinations thereof. The materials of the semiconductor layers 410 and 420 may be chosen based on providing differing oxidation rates and/or etch selectivity.

The semiconductor layers 410 and 420 can be epitaxially grown from the semiconductor substrate 302. For example, each of the semiconductor layers 410 and 420 may be grown by a molecular beam epitaxy (MBE) process, a chemical vapor deposition (CVD) process such as a metal organic CVD (MOCVD) process, and/or other suitable epitaxial growth processes. During the epitaxial growth, the crystal structure of the semiconductor substrate 302 extends upwardly, resulting in the semiconductor layers 410 and 420 having the same crystal orientation with the semiconductor substrate 302.

Upon growing the semiconductor layers 410 and 420 on the semiconductor substrate 302 (as a stack), the stack may be patterned to form one or more fin structures (e.g., 401). Each of the fin structures is elongated along a lateral direction (e.g., the Y direction), and includes a stack of patterned semiconductor layers 410-420 interleaved with each other. The fin structure 401 is formed by patterning the semiconductor layers 410-420 and the semiconductor substrate 302 using, for example, photolithography and etching techniques. For example, a mask layer (which can include multiple layers such as, for example, a pad oxide layer and an overlying pad nitride layer) is formed over the topmost semiconductor layer (e.g., 420 in FIG. 4). The pad oxide layer may be a thin film comprising silicon oxide formed, for example, using a thermal oxidation process. The pad oxide layer may act as an adhesion layer between the topmost semiconductor layer 410 (or the semiconductor layer 420 in some other embodiments) and the overlying pad nitride layer. In some embodiments, the pad nitride layer is formed of silicon nitride, silicon oxynitride, silicon carbonitride, the like, or combinations thereof. The pad nitride layer may be formed using low-pressure chemical vapor deposition (LPCVD) or plasma enhanced chemical vapor deposition (PECVD), for example.

The mask layer may be patterned using photolithography techniques. Generally, photolithography techniques utilize a photoresist material (not shown) that is deposited, irradiated (exposed), and developed to remove a portion of the photoresist material. The remaining photoresist material protects the underlying material, such as the mask layer in this example, from subsequent processing steps, such as etching. For example, the photoresist material is used to pattern the pad oxide layer and pad nitride layer to form a patterned mask.

The patterned mask can be subsequently used to pattern exposed portions of the semiconductor layers 410-420 and the substrate 302 to form trenches (or openings), thereby defining the fin structures 401 between adjacent trenches. When multiple fin structures are formed, such a trench may be disposed between any adjacent ones of the fin structures. In some embodiments, the fin structure 401 is formed by etching trenches in the semiconductor layers 410-420 and substrate 302 using, for example, reactive ion etch (RIE), neutral beam etch (NBE), the like, or combinations thereof. The etch may be anisotropic. In some embodiments, the trenches may be strips (when viewed from the top) parallel to each other, and closely spaced with respect to each other. In some embodiments, the trenches may be continuous and surround the fin structure 401.

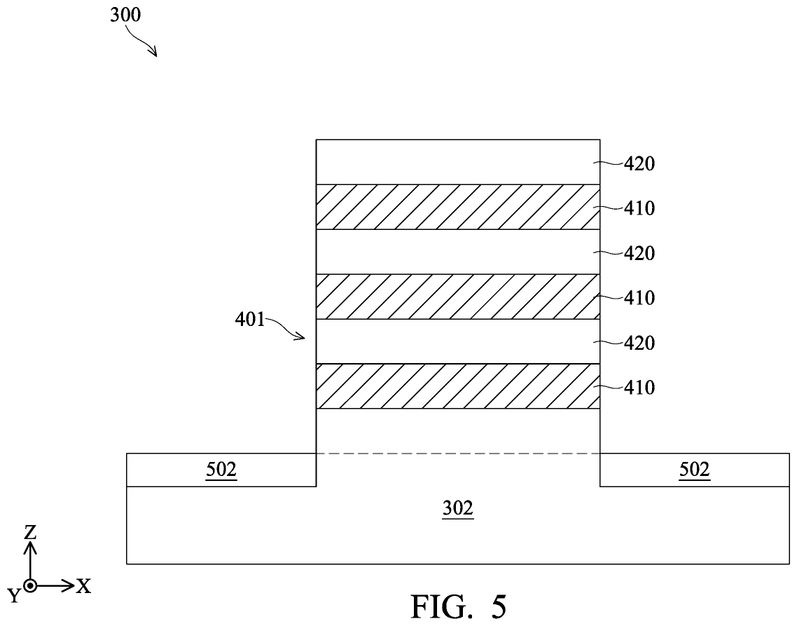

Corresponding to operation 206 of FIG. 2, FIG. 5 is a cross-sectional view of the GAA FET device 300 including one or more isolation structures 502, at one of the various stages of fabrication. The cross-sectional view of FIG. 5 is cut in a direction perpendicular to the lengthwise direction of an active/dummy gate structure of the GAA FET device 300 (e.g., cross-section A-A indicated in FIG. 1).

The isolation structure 502, which can includes multiple portions, may be formed between adjacent fin structures, or next to a single fin structure. The isolation structure 502, which are formed of an insulation material, can electrically isolate neighboring fin structures from each other. The insulation material may be an oxide, such as silicon oxide, a nitride, the like, or combinations thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. Other insulation materials and/or other formation processes may be used. In an example, the insulation material is silicon oxide formed by a FCVD process. An anneal process may be performed once the insulation material is formed. A planarization process, such as a chemical mechanical polish (CMP) process, may remove any excess insulation material and form a top surface of the insulation material and a top surface of a patterned mask (not shown) defining the fin structure 401. The patterned mask may also be removed by the planarization process, in various embodiments.

Next, the insulation material is recessed to form the isolation structure 502, as shown in FIG. 5, which is sometimes referred to as a shallow trench isolation (STI). The isolation structure 502 is recessed such that the fin structure 401 protrudes from between neighboring portions of the isolation structure 502. The top surface of the isolation structures (STIs) 502 may have a flat surface (as illustrated), a convex surface, a concave surface (such as dishing), or combinations thereof. The top surface of the isolation structure 502 may be formed flat, convex, and/or concave by an appropriate etch. The isolation structure 502 may be recessed using an acceptable etching process, such as one that is selective to the material of the isolation structure 502. For example, a dry etch or a wet etch using dilute hydrofluoric (DHF) acid may be performed to recess the isolation structure 502.

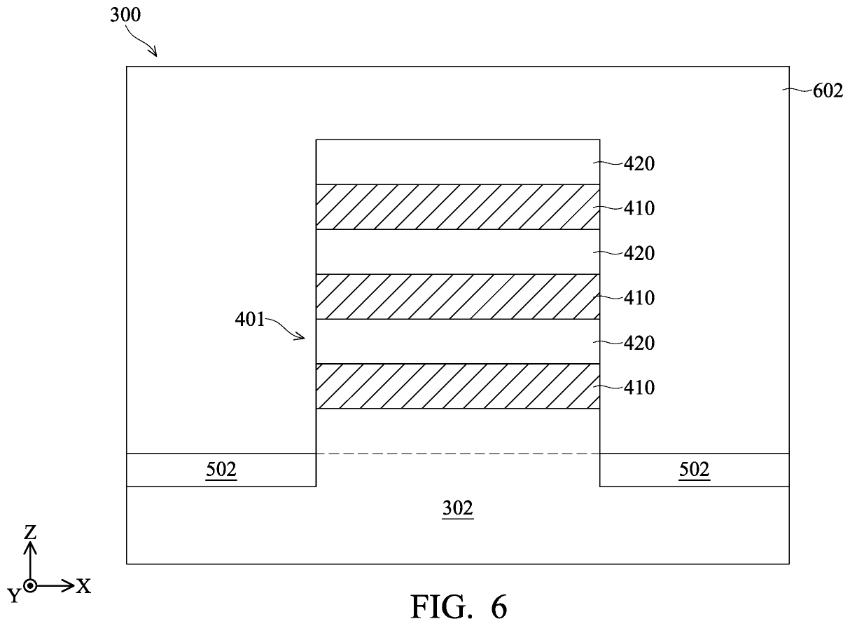

Corresponding to operation 208 of FIG. 2, FIG. 6 is a cross-sectional view of the GAA FET device 300 including a dummy gate structure 602, at one of the various stages of fabrication. The cross-sectional view of FIG. 6 is cut in a direction perpendicular to the lengthwise direction of an active/dummy gate structure of the GAA FET device 300 (e.g., cross-section A-A indicated in FIG. 1).

Next, the dummy gate structure 602 is formed over the fin structure 401 and the isolation structure 502. The dummy gate structure 602 can extend along a lateral direction (e.g., the X direction) perpendicular to the lengthwise direction of the fin structure 401. The dummy gate structure 602 may be formed in a place where an active (e.g., metal) gate structure is later formed, i.e., defining a footprint of the active gate structure, in various embodiments. In some embodiments, the dummy gate structure 602 is placed over a portion of fin structure 401. Such an overlaid portion of the fin structure 401, which includes portions of the second semiconductor layers 420 that are collectively configured as a conduction channel and portions of the first semiconductor layers 410 that are replaced with an active gate structure. As such, the active gate structure can wrap around each of the portions of the second semiconductor layers 420, which will be discussed in further detail below.

In some embodiments, the dummy gate structure 602 can include one or more Si-based or SiGe-based materials that are similar (or having similar etching rates) as the first semiconductor layers 410 such as, for example, SiGe. The dummy gate structure 602 may be deposited by CVD, PECVD, ALD, FCVD, or combinations thereof. Although the dummy gate structure 602 is shown as being formed as a single-piece in the illustrated embodiment of FIG. 6, it should be understood that the dummy gate structure 602 can be formed to have multiple portions, each of which may include respective different materials.

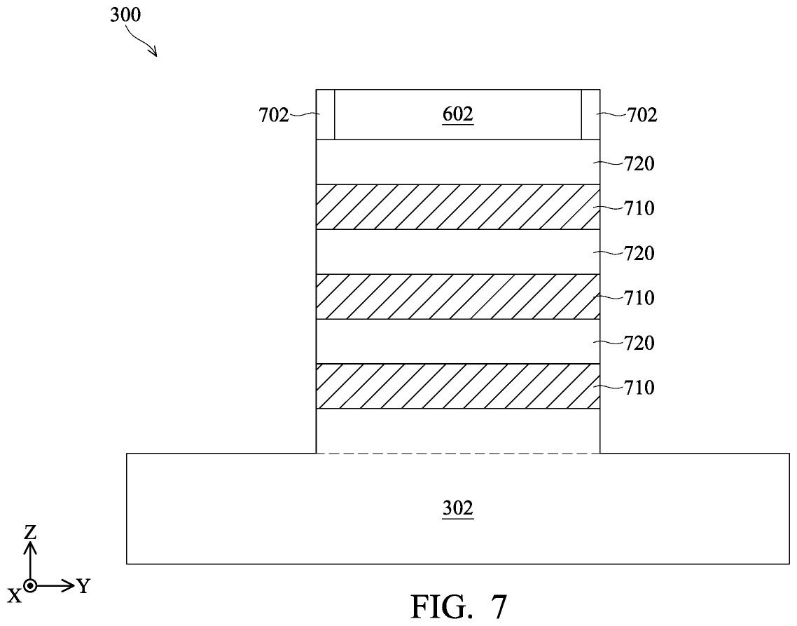

Corresponding to operation 210 of FIG. 2, FIG. 7 is a cross-sectional view of the GAA FET device 300 in which portions of the fin structure 401 that are not overlaid by the dummy gate structure 602 are removed, at one of the various stages of fabrication. The cross-sectional view of FIG. 7 is cut in the lengthwise direction of a fin structure of the GAA FET device 300 (e.g., cross-section B-B indicated in FIG. 1).

After forming the dummy gate structure 602, a pair of gate spacers 702 can be formed to extend along opposite sidewalls of the dummy gate structure 602 (in the Y direction). The gate spacers 702 may include a low-k dielectric material and may be formed of a suitable dielectric material, such as silicon oxide, silicon oxycarbonitride, or the like. Any suitable deposition method, such as thermal oxidation, chemical vapor deposition (CVD), or the like, may be used to form the gate spacers 702. The dummy gate structure 602, together with the gate spacers 702, can serve as a mask to etch the non-overlaid portions of the fin structure 401, which results in the fin structure 401 having one or more alternatingly stacks including remaining portions of the semiconductor layers 410 and 420. As a result, along the Z direction, newly formed sidewalls of each of the fin structures 401 are aligned with sidewalls of the dummy gate structure 602. For example in FIG. 7, semiconductor layers 710 and 720 are the remaining portions of the semiconductor layers 710 and 720 overlaid by the dummy gate structure 602, respectively. In some embodiments, the semiconductor layers 710 and 720 may sometimes be referred to as nanostructures (e.g., nanosheets) 710 and 720, respectively.

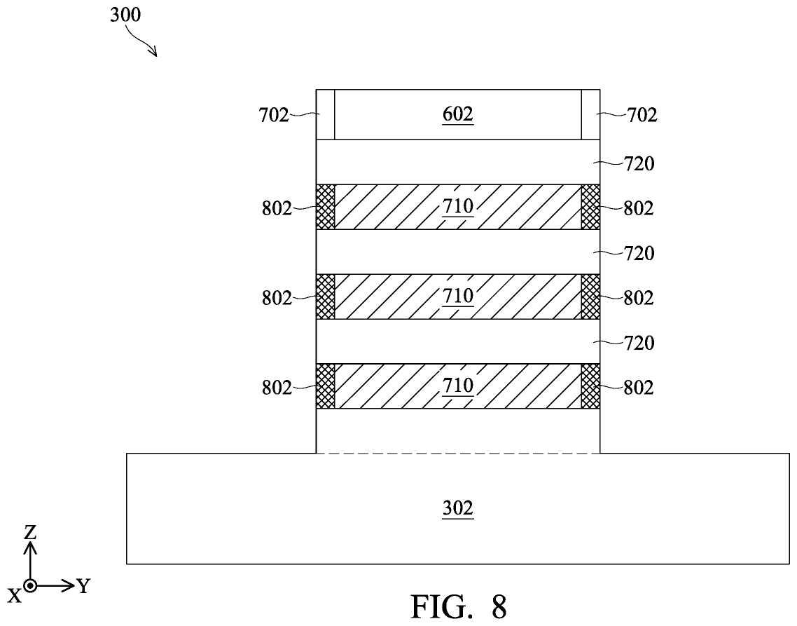

Corresponding to operation 212 of FIG. 2, FIG. 8 is a cross-sectional view of the GAA FET device 300 including a number of inner spacers 802, at one of the various stages of fabrication. The cross-sectional view of FIG. 8 is cut in the lengthwise direction of a fin structure of the GAA FET device 300 (e.g., cross-section B-B indicated in FIG. 1).

To form the inner spacers 802, respective end portions of each of the nanostructures 710 are removed. The end portions of the nanostructures 710 can be removed (e.g., etched) using a “pull-back” process to pull the nanostructures 710 back by a pull-back distance. In an example where the semiconductor layers 720 include Si, and the semiconductor layers 710 include SiGe, the pull-back process may include a hydrogen chloride (HCl) gas isotropic etch process, which etches SiGe without attacking Si. As such, the Si layers (nanostructures) 720 may remain intact during this process. Consequently, a number of pairs of recesses can be formed. These recesses are then filled with a dielectric material to form the inner spacers 802. As shown in FIG. 8, each pair of the inner spacers 802 are formed along respective etched ends of the nanostructures 710.

In some embodiments, the inner spacer 802 can be formed conformally by chemical vapor deposition (CVD), or by monolayer doping (MLD) of nitride followed by spacer RIE. The inner spacer 802 can be deposited using, e.g., a conformal deposition process and subsequent isotropic or anisotropic etch back to remove excess spacer material on the sidewalls of the stacks of the fin structure 401 and on a surface of the semiconductor substrate 302. The inner spacer 802 can be formed of silicon nitride, silicoboron carbonitride, silicon carbonitride, silicon carbon oxynitride, or any other type of dielectric material (e.g., a dielectric material having a dielectric constant k of less than about 5) appropriate to the role of forming an insulating gate sidewall spacers of transistors.

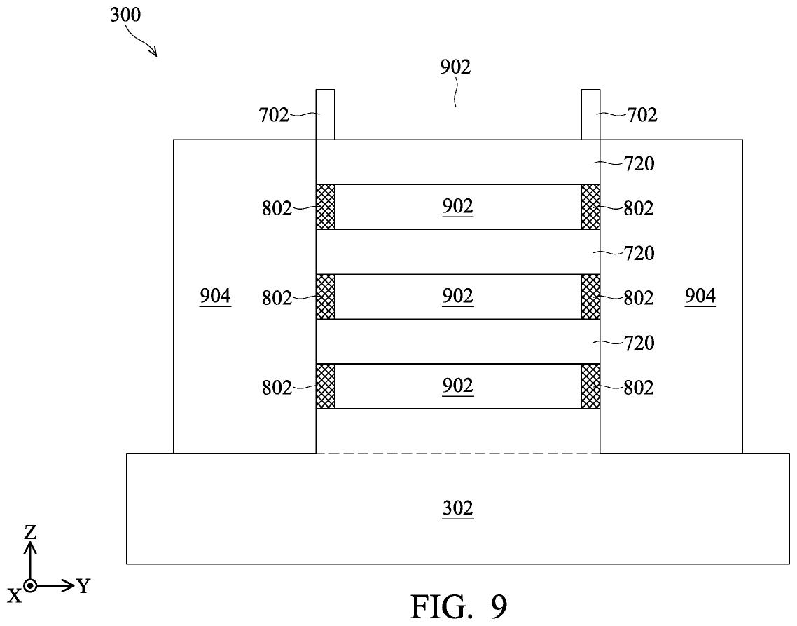

Corresponding to operation 214 of FIG. 2, FIG. 9 is a cross-sectional view of the GAA FET device 300 in which the dummy gate structure 602 and the remaining portions of the nanostructures 710 are removed so as to form a gate trench 902, at one of the various stages of fabrication. The cross-sectional view of FIG. 8 is cut in the lengthwise direction of a fin structure of the GAA FET device 300 (e.g., cross-section B-B indicated in FIG. 1).

Prior to forming the gate trench 902, at least a pair of epitaxial structures 904 may be formed to couple to respective ends of each of the nanostructures 720 (along the Y direction). Further, the epitaxial structures 904 are separated (or otherwise isolated) from respective ends (along the Y direction) of the nanostructures 710 (FIG. 8) with the inner spacers 802.

The epitaxial structures 904 may each include silicon germanium (SiGe), indium arsenide (InAs), indium gallium arsenide (InGaAs), indium antimonide (InSb), germanium arsenide (GaAs), germanium antimonide (GaSb), indium aluminum phosphide (InAlP), indium phosphide (InP), any other suitable material, or combinations thereof. The epitaxial structures 904 may be formed using an epitaxial layer growth process on exposed ends of each of the nanostructures 720. For example, the growth process can include a selective epitaxial growth (SEG) process, CVD deposition techniques (e.g., vapor-phase epitaxy (VPE) and/or ultra-high vacuum CVD (UHV-CVD)), molecular beam epitaxy, or other suitable epitaxial processes. In-situ doping (ISD) may be applied to form doped epitaxial structures 904, thereby creating the junctions for the GAA FET device 300. For example, when the GAA FET device 300 is configured in n-type, the epitaxial structures 904 can be doped by implanting n-type dopants, e.g., arsenic (As), phosphorous (P), etc., into them. When the GAA FET device 300 300 is configured in p-type, the epitaxial structures 904 can be doped by implanting p-type dopants, e.g., boron (B), etc., into them.

Following the formation of the epitaxial structures 904, the dummy gate structure 602 and the nanostructures 710 (FIG. 8) may be collectively or respectively removed to form the gate trench 902. In some embodiments, the dummy gate structure 602 and/or the nanostructures 710 can be removed by applying a selective etch (e.g., a hydrochloric acid (HCl)), while leaving the nanostructures 720, the gate spacers 702, and inner spacers 802 substantially intact. After the removal of the dummy gate structure 602, a portion of the gate trench 902, exposing respective sidewalls of each of the nanostructures 720 that face the X direction, may be formed. After the removal of the nanostructures 710 to further extend the gate trench 902, respective bottom surface and/or top surface of each of the nanostructures 720 may be exposed. Consequently, a full circumference of each of the nanostructures 720 can be exposed.

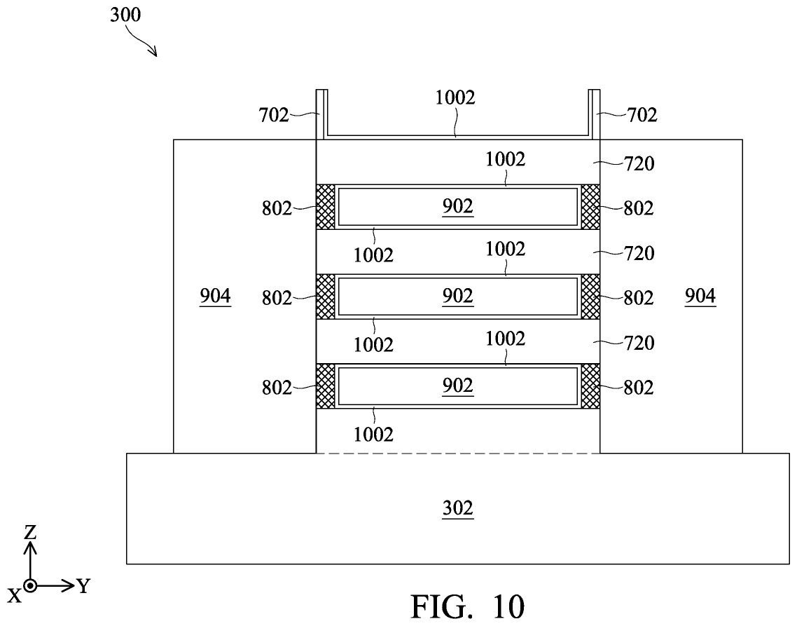

Corresponding to operation 216 of FIG. 2, FIG. 10 is a cross-sectional view of the GAA FET device 300 including an interfacial layer 1002 formed to wrap around each of the nanostructures 720, at one of the various stages of fabrication. The cross-sectional view of FIG. 10 is cut in the lengthwise direction of a fin structure of the GAA FET device 300 (e.g., cross-section B-B indicated in FIG. 1).

As shown in the cross-sectional view of FIG. 10, the interfacial layer 1002 is formed within each portion of the gate trench 902. Specifically, the interfacial layer 1002 may wrap around the circumference of each of the nanostructures 720. The interfacial layer 1002 may include silicon, oxygen, and/or nitrogen. In an embodiment, the interfacial layer 1002 may include SiO₂. The interfacial layer 1002 may be formed by atomic layer deposition (ALD), wet cleaning, thermal oxidation, and/or other suitable process.

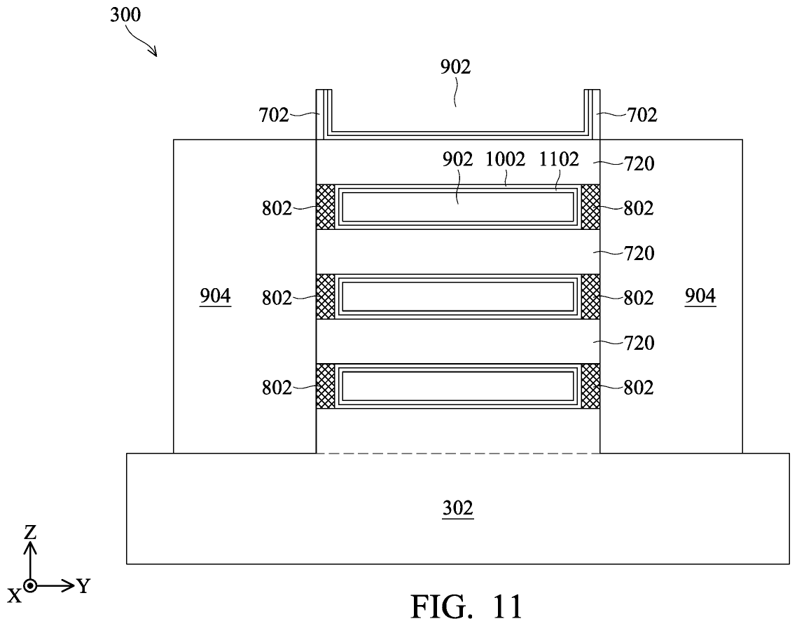

Corresponding to operation 218 of FIG. 2, FIG. 11 is a cross-sectional view of the GAA FET device 300 including a first high-k dielectric layer 1102 formed over the interfacial layer 1002, at one of the various stages of fabrication. The cross-sectional view of FIG. 10 is cut in the lengthwise direction of a fin structure of the GAA FET device 300 (e.g., cross-section B-B indicated in FIG. 1).

As shown in the cross-sectional view of FIG. 11, the first high-k dielectric layer 1102 is formed within each portion of the gate trench 902. Specifically, the first high-k dielectric layer 1102 may wrap around the interfacial layer 1002, i.e., further wrapping around the circumference of each of the nanostructures 720. The first high-k dielectric layer 1102 may have a k value greater than about 7.0, and may include a metal oxide or a silicate of Hf, Al, Zr, La, Mg, Ba, Ti, Pb, or combinations thereof. The formation methods of first high-k dielectric layer 1102 may include molecular beam deposition (MBD), atomic layer deposition (ALD), PECVD, and the like. In some embodiments, the first high-k dielectric layer 1102 may be modified (e.g., doped) through an interface dipole engineering so as to adjust the flat band voltage of a corresponding active (e.g., metal) gate structure. Different flat band voltages can correspond to different threshold voltages. In this way, a plural number of transistors having respectively different threshold voltages can be formed through such an adjustment on the flat band voltage, which will be discussed below.

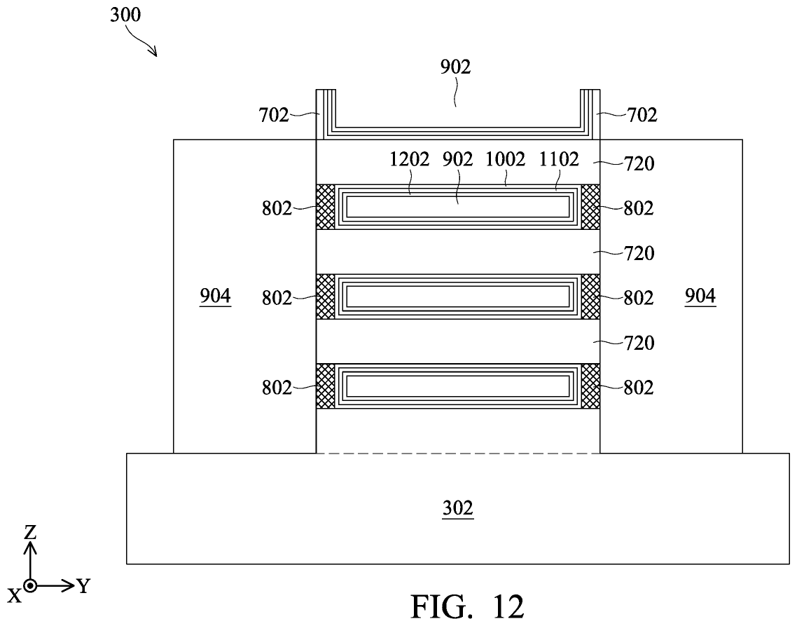

Corresponding to operation 220 of FIG. 2, FIG. 12 is a cross-sectional view of the GAA FET device 300 including one or more threshold voltage modulation layers 1202 formed over the first high-k dielectric layer 1102, at one of the various stages of fabrication. The cross-sectional view of FIG. 10 is cut in the lengthwise direction of a fin structure of the GAA FET device 300 (e.g., cross-section B-B indicated in FIG. 1).

In some embodiments, the threshold voltage modulation layer 1202 may include a dielectric material selected from the group consisting of: lanthanum(III) oxide (La₂O₃), lutetium oxide (LuO), scandium oxide (ScO), yttrium oxide (Y₂O₃), Thulium(III) oxide (Tm₂O₃), gadolinium(III) oxide (Gd₂O₃), zinc oxide (ZnO), germanium oxide (GeO), aluminum(II) oxide (AlO), titanium(II) oxide (TiO), vanadium(II) oxide (VO), and combinations thereof. The formation methods of threshold voltage modulation layer 1202 may include molecular beam deposition (MBD), atomic layer deposition (ALD), PECVD, and the like. The threshold voltage modulation layer 1202, upon being annealed, may induce a dipole-interface between itself and the underlying first high-k dielectric layer 1102, which can change the flat band voltage of a corresponding active gate structure that utilizes the first high-k dielectric layer 1102 as a part of its gate dielectric layer. As such, the active gate structures of different conductive types may be formed based on respectively different threshold voltage modulation layers (thus different compositions of the first high-k dielectric layer). For example, lanthanum(III) oxide (La₂O₃), lutetium oxide (LuO), scandium oxide (ScO), yttrium oxide (Y₂O₃), Thulium(III) oxide (Tm₂O₃), gadolinium(III) oxide (Gd₂O₃), or combinations thereof may be utilized to form an n-type transistor, while zinc oxide (ZnO), germanium oxide (GeO), aluminum(II) oxide (AlO), titanium(II) oxide (TiO), vanadium(II) oxide (VO), or combinations thereof may be utilized to form a p-type transistor.

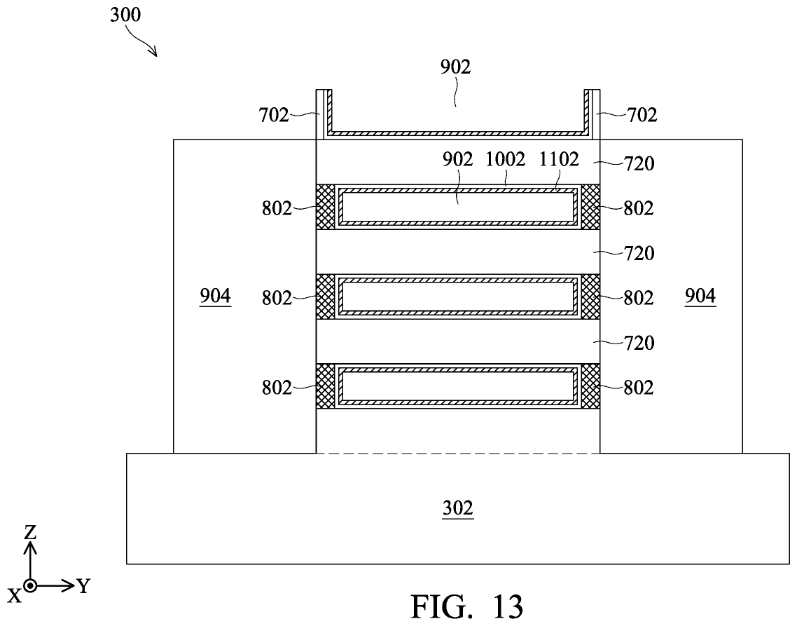

Corresponding to operation 222 of FIG. 2, FIG. 13 is a cross-sectional view of the GAA FET device 300 in which a first annealing process is performed, followed by removing the one or more threshold voltage modulation layers 1202, at one or more of the various stages of fabrication. The cross-sectional view of FIG. 13 is cut in the lengthwise direction of a fin structure of the GAA FET device 300 (e.g., cross-section B-B indicated in FIG. 1).

As mentioned above, the first annealing process can cause a dipole-interface to be formed between itself and the underlying first high-k dielectric layer 1102. Specifically, through the first annealing process, a number of dipoles can be formed along the surface of the first high-k dielectric layer 1102 (i.e., the interface between the first high-k dielectric layer 1102 and the threshold voltage modulation layer 1202). The first annealing process may be performed around about 500° C. and 700° C. for about 10 to 30 seconds. After the first high-k dielectric layer 1102 being modified (hereinafter “modified first high-k dielectric layer 1102”), the one or more threshold voltage modulation layer 1202 may be removed through a wet etching process.

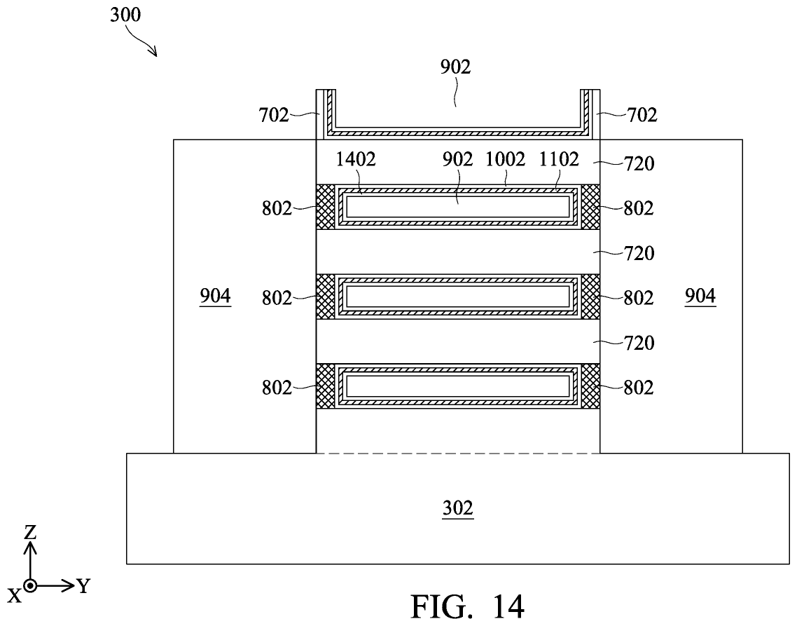

Corresponding to operation 224 of FIG. 2, FIG. 14 is a cross-sectional view of the GAA FET device 300 including a second high-k dielectric layer 1402 formed over the first high-k dielectric layer 1102, at one of the various stages of fabrication. The cross-sectional view of FIG. 14 is cut in the lengthwise direction of a fin structure of the GAA FET device 300 (e.g., cross-section B-B indicated in FIG. 1).

As shown in the cross-sectional view of FIG. 14, the second high-k dielectric layer 1402 is formed within each portion of the gate trench 902. Specifically, the second high-k dielectric layer 1402 may wrap around the first high-k dielectric layer 1102, i.e., further wrapping around the circumference of each of the nanostructures 720. The second high-k dielectric layer 1402 may have a k value greater than about 7.0, and may include a metal oxide or a silicate of Hf, Al, Zr, La, Mg, Ba, Ti, Pb, or combinations thereof. The formation methods of second high-k dielectric layer 1402 may include molecular beam deposition (MBD), atomic layer deposition (ALD), PECVD, and the like.

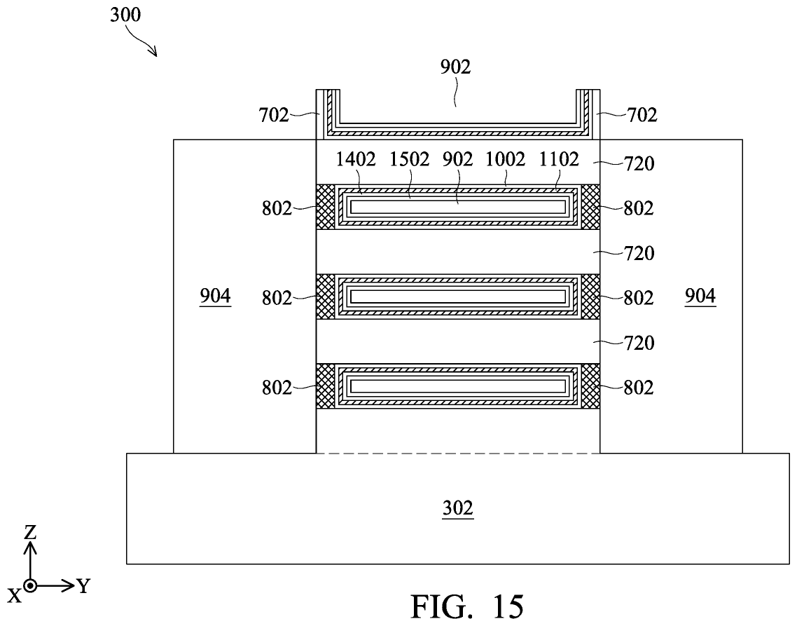

Corresponding to operation 226 of FIG. 2, FIG. 15 is a cross-sectional view of the GAA FET device 300 including a ruthenium-containing layer 1502 formed over the second high-k dielectric layer 1402, at one of the various stages of fabrication. The cross-sectional view of FIG. 15 is cut in the lengthwise direction of a fin structure of the GAA FET device 300 (e.g., cross-section B-B indicated in FIG. 1).

In some embodiments, the ruthenium-containing layer 1502 may essentially consist of ruthenium or ruthenium oxide. The formation methods of ruthenium-containing layer 1502 may include molecular beam deposition (MBD), atomic layer deposition (ALD), PECVD, and the like.

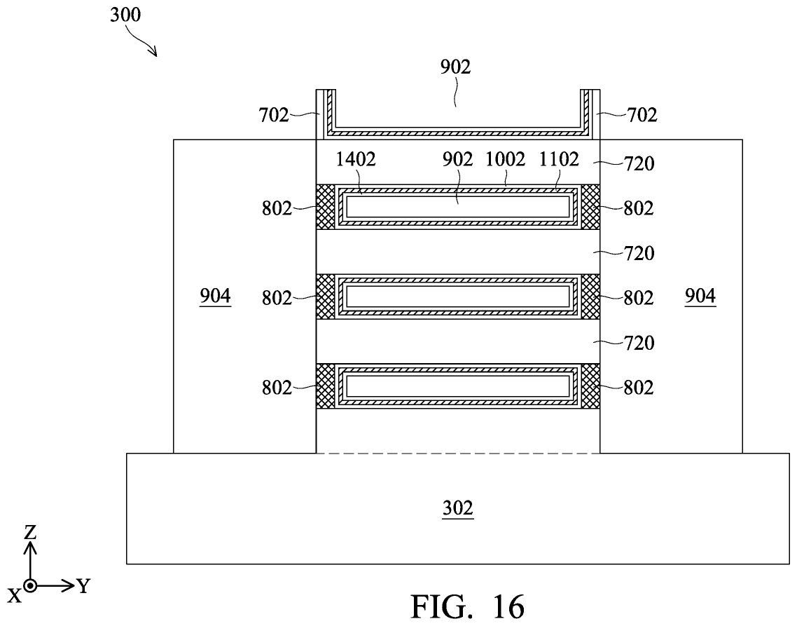

Corresponding to operation 228 of FIG. 2, FIG. 16 is a cross-sectional view of the GAA FET device 300 in which a second annealing process is performed, followed by removing the ruthenium-containing layer 1502, at one or more of the various stages of fabrication. The cross-sectional view of FIG. 16 is cut in the lengthwise direction of a fin structure of the GAA FET device 300 (e.g., cross-section B-B indicated in FIG. 1).

By performing the second annealing process on at least the ruthenium-containing layer 1502, any oxygen vacancies present in the first high-k dielectric layer 1102 and/or second high-k dielectric layer 1402 can be eliminated. For example, oxygen atoms contained in the ruthenium-containing layer 1502 (inherently formed along surfaces of the ruthenium-containing layer 1502), through the second annealing process, may be diffused (or pushed) into the first high-k dielectric layer 1102 and/or second high-k dielectric layer 1402 to fill up the oxygen vacancies therein. As such, a quality of the first high-k dielectric layer 1102 and/or second high-k dielectric layer 1402 can be greatly improved. In some embodiments, the second annealing process may be performed at a relatively low temperature (with respect to the first annealing process), for example, not greater than about 550° C. As such, a total amount of the thermal budget to fabricate the GAA FET device 300 can be significantly reduced.

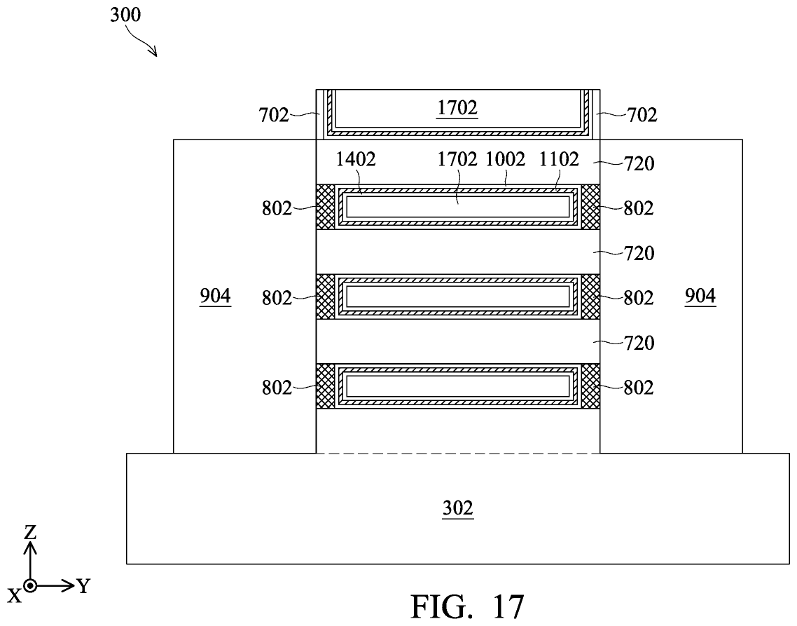

Corresponding to operation 230 of FIG. 2, FIG. 17 is a cross-sectional view of the GAA FET device 300 including one or more work function metal layers 1702 formed over the second high-k dielectric layer 1402, at one of the various stages of fabrication. The cross-sectional view of FIG. 17 is cut in the lengthwise direction of a fin structure of the GAA FET device 300 (e.g., cross-section B-B indicated in FIG. 1).

In some embodiments, the one or more work function metal layers 1702 can be formed over the second high-k dielectric layer 1402 to fill the gate trench 902, as shown in FIG. 17. The interfacial layer 1002, the first high-k dielectric layer 1102, the second high-k dielectric layer 1402, and the work function metal layers 1702 may be collectively referred to as a an active (e.g., metal) gate structure of the GAA FET device 300. Such an active gate structure can wrap around each of the nanostructures 720, in which the nanostructures 720 can collectively function as a conduction channel of the GAA FET device 300 with epitaxial structures 904 functioning as a source and a drain of the GAA FET device 300.

The work function metal layers 1702 may include a p-type work function layer, an n-type work function layer, multi-layers thereof, or combinations thereof. Example p-type work function metals that may include TiN, TaN, Ru, Mo, Al, WN, ZrSi₂, MoSi₂, TaSiz, NiSi₂, WN, other suitable p-type work function materials, or combinations thereof. Example n-type work function metals that may include Ti, Ag, TaAl, TaAlC, TiAlN, TaC, TaCN, TaSiN, Mn, Zr, other suitable n-type work function materials, or combinations thereof. A work function value is associated with the material composition of the work function layer, and thus, the material of the work function layer is chosen to tune its work function value so that a target threshold voltage Vi is achieved in the device that is to be formed. The work function metal layer(s) 1702 may be deposited by CVD, physical vapor deposition (PVD), ALD, and/or other suitable process.

In some other embodiments, instead of utilizing the work function metal layers 1702 as a gate metal of the GAA FET device 300, the ruthenium-containing layer 1502 may serve as the gate metal. Alternatively stated, the interfacial layer 1002, the first high-k dielectric layer 1102, the second high-k dielectric layer 1402, and the ruthenium-containing layer 1502 may collectively serve as the active (e.g., metal) gate structure of the GAA FET device 300. As such, after performing the second annealing process, the ruthenium-containing layer 1502 may remain. Further, in operation 226 (of depositing the ruthenium-containing layer 1502), the ruthenium-containing layer 1502 may have filled up the gate trench 902.

According to various embodiments of the present disclosure, each operation of the method 200 can be concurrently performed on various areas of a substrate to fabricate a plural number of transistors (e.g., GAA FET devices) that have respectively different threshold voltages. FIGS. 18, 19, 20, 21, 22, 23, 24, 25, 26, 27, 28, 29, 30, 31, and 32 respectively illustrate a number of fabrication stages to form six different transistors, one or more of which may correspond to operation of the method 200. In the following discussion, these six transistors (from the left to the right) are herein referred to as “transistor A,” “transistor B,” “transistor C,” “transistor D,” “transistor E,” and “transistor F,” respectively.

In FIG. 18, after forming the gate trench for each of the transistors A to F (i.e., exposing their respective nanostructures 720A, 720B, 720C, 720D, 720E, and 720F), an interfacial layer 1002 may be universally formed over the transistors A to F to wrap around each of their respective nanostructures 720A to 720F (corresponding to operation 216). Next in FIG. 19, which may correspond to operation 218, a first high-k dielectric layer 1102 may be universally formed over the transistors A to F.

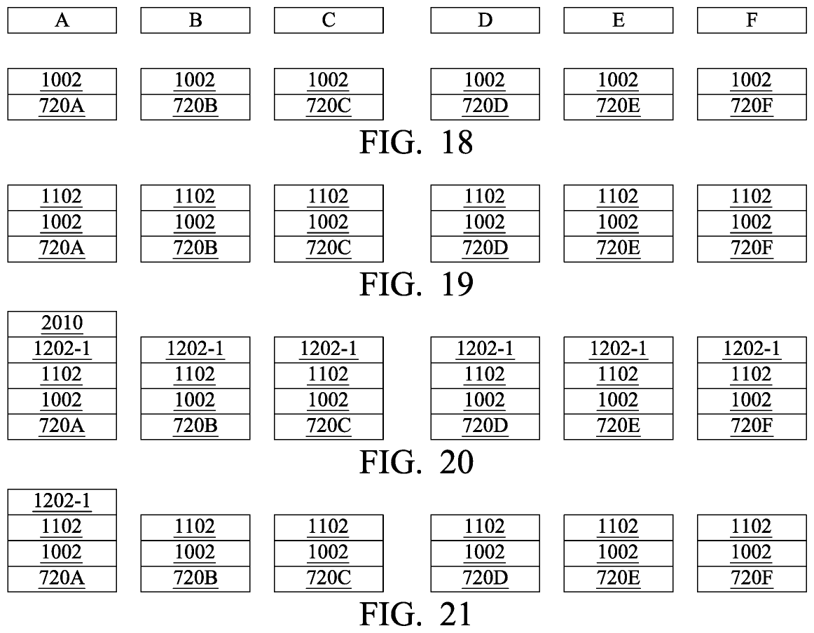

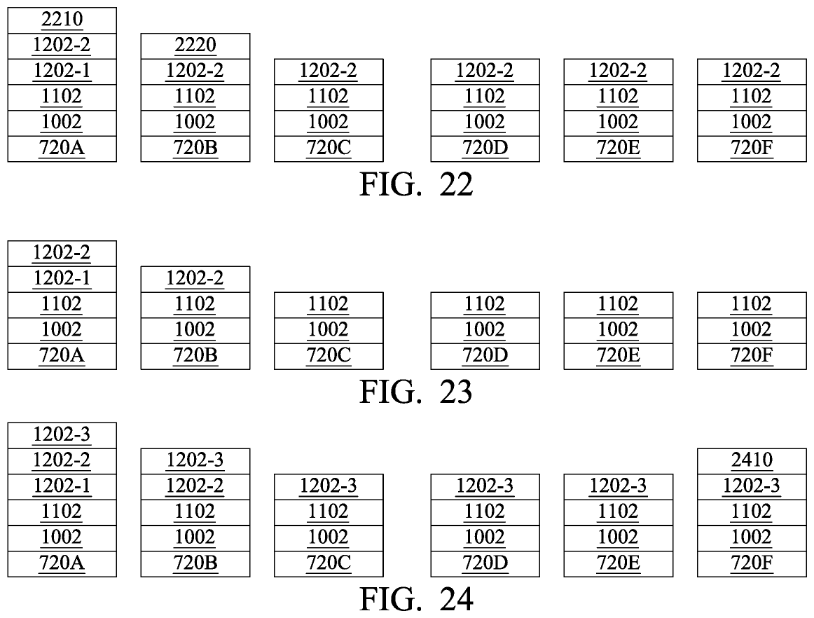

Next in FIG. 20, which may correspond to operation 220, a first voltage threshold modulation layer 1202-1 may be universally formed over the transistors A to F. In some embodiments, the first voltage threshold modulation layer 1202-1 may be selected from one of: lanthanum(III) oxide (La₂O₃), lutetium oxide (LuO), scandium oxide (ScO), yttrium oxide (Y₂O₃), Thulium(III) oxide (Tm₂O₃), gadolinium(III) oxide (Gd₂O₃), and combinations thereof. Following the universal formation of the first voltage threshold modulation layer 1202-1, a patterned layer 2010 may be formed to mask the transistor A, with the first voltage threshold modulation layers 1202-1 formed over the transistors B to F being exposed. Accordingly next in FIG. 21 where the exposed first voltage threshold modulation layers 1202-1 are removed, only the first high-k dielectric layer 1102 of the transistor A is wrapped by the first voltage threshold modulation layer 1202-1. Next in FIG. 22, a second voltage threshold modulation layer 1202-2 may be universally formed over the transistors A to F. In some embodiments, the second voltage threshold modulation layer 1202-2 may be selected from one of: lanthanum(III) oxide (La₂O₃), lutetium oxide (LuO), scandium oxide (ScO), yttrium oxide (Y₂O₃), Thulium(III) oxide (Tm₂O₃), gadolinium(III) oxide (Gd₂O₃), and combinations thereof. Following the universal formation of the second voltage threshold modulation layer 1202-2, patterned layers 2210 and 2220 may be formed to mask the transistor A and transistor B, respectively, with the second voltage threshold modulation layers 1202-2 formed over the transistors C to F being exposed. Accordingly next in FIG. 23 where the exposed second voltage threshold modulation layers 1202-2 are removed, only the first high-k dielectric layer 1102 of the transistor A is wrapped by the first voltage threshold modulation layer 1202-1 and second voltage threshold modulation layer 1202-2, and only the first high-k dielectric layer 1102 of the transistor B is wrapped by the second voltage threshold modulation layer 1202-2.

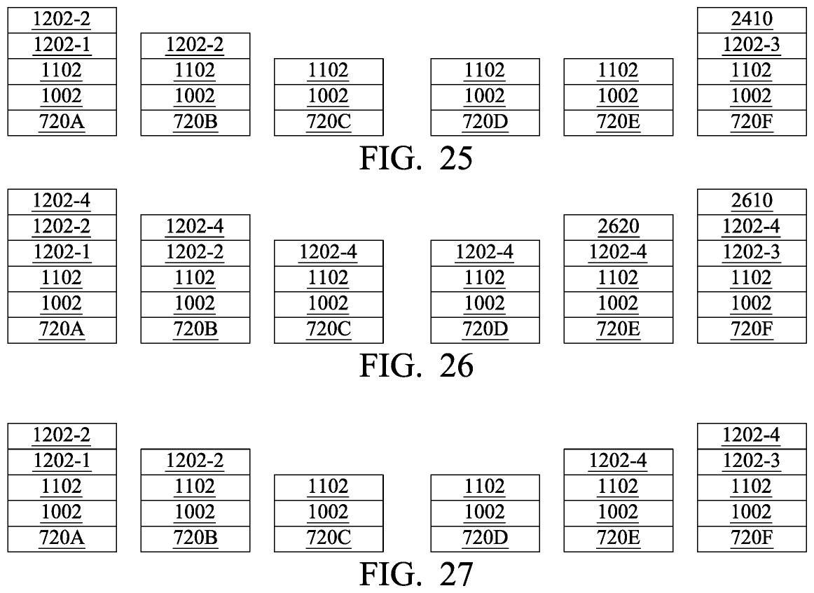

Next in FIG. 24, which may still correspond to operation 220, a third voltage threshold modulation layer 1202-3 may be universally formed over the transistors A to F. In some embodiments, the third voltage threshold modulation layer 1202-3 may be selected from one of: zinc oxide (ZnO), germanium oxide (GeO), aluminum(II) oxide (AlO), titanium(II) oxide (TiO), vanadium(II) oxide (VO), or combinations thereof. Following the universal formation of the third voltage threshold modulation layer 1202-3, a patterned layer 2410 may be formed to mask the transistor F, with the third voltage threshold modulation layers 1202-3 formed over the transistors A to E being exposed. Accordingly next in FIG. 25 where the exposed third voltage threshold modulation layers 1202-3 are removed, only the first high-k dielectric layer 1102 of the transistor F is wrapped by the third voltage threshold modulation layer 1202-3. Next in FIG. 26, a fourth voltage threshold modulation layer 1202-4 may be universally formed over the transistors A to F. In some embodiments, the fourth voltage threshold modulation layer 1202-4 may be selected from one of: zinc oxide (ZnO), germanium oxide (GeO), aluminum(II) oxide (AlO), titanium(II) oxide (TiO), vanadium(II) oxide (VO), or combinations thereof. Following the universal formation of the fourth voltage threshold modulation layer 1202-4, patterned layers 2610 and 2620 may be formed to mask the transistor F and transistor E, respectively, with the fourth voltage threshold modulation layers 1202-4 formed over the transistors A to D being exposed. Accordingly next in FIG. 27 where the exposed fourth voltage threshold modulation layers 1202-4 are removed, only the first high-k dielectric layer 1102 of the transistor F is wrapped by the third voltage threshold modulation layer 1202-3 and fourth voltage threshold modulation layer 1202-4, and only the first high-k dielectric layer 1102 of the transistor E is wrapped by the fourth voltage threshold modulation layer 1202-4.

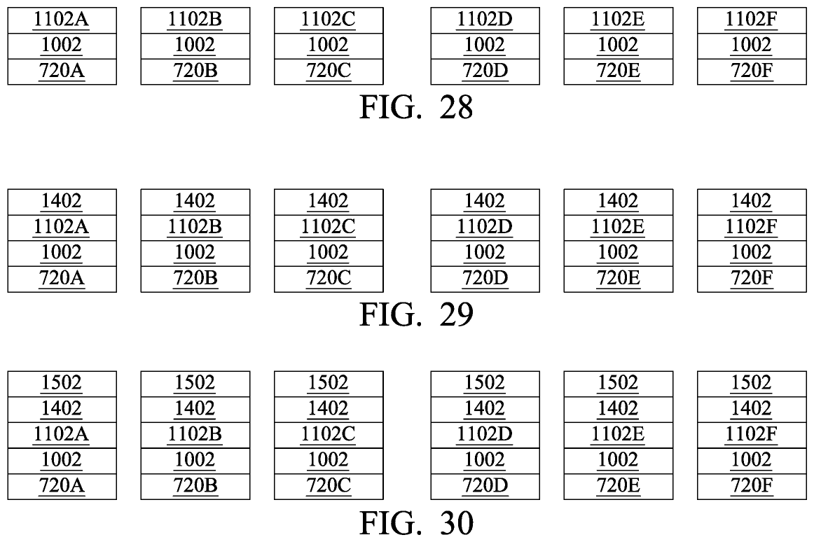

Next in FIG. 28, which may correspond to operation 222, a first annealing process is performed to modify the first high-k dielectric layers 1102 of the transistors A to F, respectively, as discussed above. It is sometimes referred to as driving different dopants or different amounts of dopants into the first high-k dielectric layers 1102 of the transistors A to F, which are herein referred to as “first high-k dielectric layers 1102A,” “first high-k dielectric layers 1102B,” “first high-k dielectric layers 1102C,” “first high-k dielectric layers 1102D,” “first high-k dielectric layers 1102E,” and “first high-k dielectric layers 1102F,” respectively. After the drive-in process, the “remaining” threshold voltage modulation layers may be removed from the transistors, e.g., A, B, E, and F.

Next in FIG. 29, which may correspond to operation 224, a second high-k dielectric layer 1402 may be universally formed over the transistors A to F. As such, each of the first high-k dielectric layers 1102A to 1102F may be wrapped by the universally formed second high-k dielectric layer 1402.

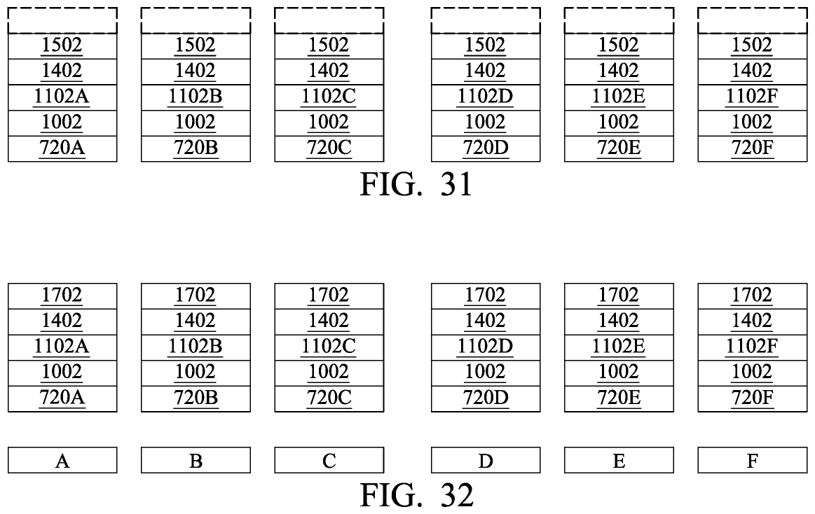

Next in FIG. 30, which may correspond to operation 226, a ruthenium-containing layer 1502 may be universally formed over the transistors A to F. As such, each of the first high-k dielectric layers 1102A to 1102F may be further wrapped by the universally formed ruthenium-containing layer 1502. Next in FIG. 31, which may correspond to operation 228, a second annealing process may be performed to use the ruthenium-containing layer 1502 to cure oxygen vacancies present in at least one of first high-k dielectric layers 1102A to 1102F or the second high-k dielectric layer 1402, if there are any. Next in FIG. 32, which may correspond to operation 230, a work function metal layer 1702 may be universally formed over the transistors A to F. Even though the work function metal layer 1702 is universally formed over the transistors A to F, with their first high-k dielectric layers 1102A to 1102F being modified differently, the transistors A to F can still have respective different threshold voltages.

In one aspect of the present disclosure, a method for fabricating a semiconductor device is disclosed. The method includes exposing one or more surfaces of a conduction channel of a transistor; overlaying the one or more surfaces with a first high-k dielectric layer; overlaying the first high-k dielectric layer with a second high-k dielectric layer; depositing a ruthenium-containing layer over the second high-k dielectric layer; and performing a first annealing process with a temperature not greater than a threshold so as to remove oxygen vacancies from at least the first high-k dielectric layer.

In another aspect of the present disclosure, a method for fabricating a semiconductor device is disclosed. The method includes exposing one or more surfaces of a first conduction channel of a first transistor; exposing one or more surfaces of a second conduction channel of a second transistor; overlaying the one or more surfaces of the first conduction channel with a first high-k dielectric layer and the one or more surfaces of the second conduction channel with a second high-k dielectric layer, respectively; forming a first combination of threshold voltage modulation layers over the first high-k dielectric layer; forming a second combination of threshold voltage modulation layers over the second high-k dielectric layer; performing a first annealing process on at least the first combination of threshold voltage modulation layers and the second combination of threshold voltage modulation layers; removing the first combination of threshold voltage modulation layers and the second combination of threshold voltage modulation layers; overlaying the first high-k dielectric layer with a third high-k dielectric layer and the second high-k dielectric layer with a fourth high-k dielectric layer, respectively; depositing a ruthenium-containing layer over each of the third high-k dielectric layer and the fourth high-k dielectric layer; and performing a second annealing process with a temperature not greater than a threshold so as to remove oxygen vacancies from at least the first high-k dielectric layer and from the second high-k dielectric layer.

In yet another aspect of the present disclosure, a method for fabricating a semiconductor device is disclosed. The method includes exposing one or more surfaces of a first conduction channel of a first transistor configured with a first threshold voltage; exposing one or more surfaces of a second conduction channel of a second transistor configured with a second threshold voltage, the second threshold voltage different from the first threshold voltage; wrapping the one or more surfaces of the first conduction channel with a first high-k dielectric layer and the one or more surfaces of the second conduction channel with a second high-k dielectric layer, respectively; wrapping the first high-k dielectric layer with a first combination of threshold voltage modulation layers; forming the second high-k dielectric layer with a second combination of threshold voltage modulation layers; performing a first annealing process on at least the first combination of threshold voltage modulation layers and the second combination of threshold voltage modulation layers; removing the first combination of threshold voltage modulation layers and the second combination of threshold voltage modulation layers; wrapping the first high-k dielectric layer with a third high-k dielectric layer and the second high-k dielectric layer with a fourth high-k dielectric layer, respectively; wrapping each of the third high-k dielectric layer and the fourth high-k dielectric layer with a ruthenium-containing layer; and performing a second annealing process to remove oxygen vacancies from at least the first high-k dielectric layer and from the second high-k dielectric layer.

As used herein, the terms “about” and “approximately” generally mean plus or minus a certain percentage of the stated value, depending on a technology node applied to the present disclosure. For example, the percentage may be equal to 10%, such that about 0.5 would include 0.45 and 0.55, about 10 would include 9 to 11, about 1000 would include 900 to 1100, and so on. In another example, the percentage may be equal to 20%, such that about 0.5 would include 0.4 and 0.6, about 10 would include 8 to 12, about 1000 would include 800 to 1200, and so on. In yet another example, the percentage may be equal to 30%, such that about 0.5 would include 0.35 and 0.65, about 10 would include 7 to 13, about 1000 would include 700 to 1300, and so on.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating a semiconductor device, comprising:
exposing one or more surfaces of a conduction channel of a transistor;
overlaying the one or more surfaces with a first high-k dielectric layer;
overlaying the first high-k dielectric layer with a second high-k dielectric layer;
depositing a ruthenium-containing layer over the second high-k dielectric layer; and
performing a first annealing process with a temperature not greater than a threshold so as to remove oxygen vacancies from at least the first high-k dielectric layer.

2. The method of claim 1, wherein the conduction channel includes a plurality of nanostructures vertically spaced from one another.

3. The method of claim 1, prior to the step of overlaying the first high-k dielectric layer with a second high-k dielectric layer, further comprising:
forming one or more threshold voltage modulation layers over the first high-k dielectric layer;
performing a second annealing process at least on the one or more threshold voltage modulation layers; and
removing the one or more threshold voltage modulation layers.

4. The method of claim 3, wherein the one or more threshold voltage modulation layers are selected from a group consisting of: lanthanum(III) oxide (La₂O₃), lutetium oxide (LuO), scandium oxide (ScO), yttrium oxide (Y₂O₃), Thulium(III) oxide (Tm₂O₃), gadolinium(III) oxide (Gd₂O₃), and combinations thereof.

5. The method of claim 3, wherein the one or more threshold voltage modulation layers are selected from a group consisting of: zinc oxide (ZnO), germanium oxide (GeO), aluminum(II) oxide (AlO), titanium(II) oxide (TiO), vanadium(II) oxide (VO), and combinations thereof.

6. The method of claim 1, wherein the ruthenium-containing layer essentially consists of ruthenium or ruthenium oxide.

7. The method of claim 1, subsequently to the step of performing a first annealing process, further comprising:
removing the ruthenium-containing layer;
forming one or more work function metal layers over the second high-k dielectric layer; and
forming an interconnect structure in contact with at least a portion of the one or more work function metal layers.

8. The method of claim 1, subsequently to the step of performing a first annealing process, further comprising:
retaining the ruthenium-containing layer; and
forming an interconnect structure in contact with at least a portion of the ruthenium-containing layer.

9. The method of claim 1, wherein the threshold is about 550° C.

10. A method for fabricating a semiconductor device, comprising:
exposing one or more surfaces of a first conduction channel of a first transistor;
exposing one or more surfaces of a second conduction channel of a second transistor;
overlaying the one or more surfaces of the first conduction channel with a first high-k dielectric layer and the one or more surfaces of the second conduction channel with a second high-k dielectric layer, respectively;
forming a first combination of threshold voltage modulation layers over the first high-k dielectric layer;
forming a second combination of threshold voltage modulation layers over the second high-k dielectric layer;
performing a first annealing process on at least the first combination of threshold voltage modulation layers and the second combination of threshold voltage modulation layers;
removing the first combination of threshold voltage modulation layers and the second combination of threshold voltage modulation layers;
overlaying the first high-k dielectric layer with a third high-k dielectric layer and the second high-k dielectric layer with a fourth high-k dielectric layer, respectively;
depositing a ruthenium-containing layer over each of the third high-k dielectric layer and the fourth high-k dielectric layer; and
performing a second annealing process with a temperature not greater than a threshold so as to remove oxygen vacancies from at least the first high-k dielectric layer and from the second high-k dielectric layer.

11. The method of claim 10, wherein each of the first conduction channel and second conduction channel includes a plurality of nanostructures vertically spaced from one another.

12. The method of claim 10, wherein the threshold voltage modulation layers are selected from a group consisting of: lanthanum(III) oxide (La₂O₃), lutetium oxide (LuO), scandium oxide (ScO), yttrium oxide (Y₂O₃), Thulium(III) oxide (Tm₂O₃), gadolinium(III) oxide (Gd₂O₃), zinc oxide (ZnO), germanium oxide (GeO), aluminum(II) oxide (AlO), titanium(II) oxide (TiO), vanadium(II) oxide (VO), and combinations thereof.

13. The method of claim 10, wherein the first combination of threshold voltage modulation layers are configured to provide the first transistor with a first threshold voltage, and the second combination of threshold voltage modulation layers are configured to provide the second transistor with a second threshold voltage.

14. The method of claim 10, wherein the threshold is about 550° C.

15. The method of claim 10, after the second annealing process, further comprising:
removing the ruthenium-containing layer; and
forming at least one work function metal layer over each of the third high-k dielectric layer and the fourth high-k dielectric layer.

16. The method of claim 10, wherein the ruthenium-containing layer essentially consists of ruthenium or ruthenium oxide.

17. A method for fabricating a semiconductor device, comprising:
exposing one or more surfaces of a first conduction channel of a first transistor configured with a first threshold voltage;
exposing one or more surfaces of a second conduction channel of a second transistor configured with a second threshold voltage, the second threshold voltage different from the first threshold voltage;
wrapping the one or more surfaces of the first conduction channel with a first high-k dielectric layer and the one or more surfaces of the second conduction channel with a second high-k dielectric layer, respectively;
wrapping the first high-k dielectric layer with a first combination of threshold voltage modulation layers;
forming the second high-k dielectric layer with a second combination of threshold voltage modulation layers;
performing a first annealing process on at least the first combination of threshold voltage modulation layers and the second combination of threshold voltage modulation layers;
removing the first combination of threshold voltage modulation layers and the second combination of threshold voltage modulation layers;
wrapping the first high-k dielectric layer with a third high-k dielectric layer and the second high-k dielectric layer with a fourth high-k dielectric layer, respectively;
wrapping each of the third high-k dielectric layer and the fourth high-k dielectric layer with a ruthenium-containing layer; and
performing a second annealing process to remove oxygen vacancies from at least the first high-k dielectric layer and from the second high-k dielectric layer.

18. The method of claim 17, wherein a temperature of the second annealing process is equal to or less than about 550° C.

19. The method of claim 17, wherein the ruthenium-containing layer essentially consists of ruthenium or ruthenium oxide.

20. The method of claim 17, wherein the threshold voltage modulation layers are selected from a group consisting of: lanthanum(III) oxide (La₂O₃), lutetium oxide (LuO), scandium oxide (ScO), yttrium oxide (Y₂O₃), Thulium(III) oxide (Tm₂O₃), gadolinium(III) oxide (Gd₂O₃), zinc oxide (ZnO), germanium oxide (GeO), aluminum(II) oxide (AlO), titanium(II) oxide (TiO), vanadium(II) oxide (VO), and combinations thereof.
